(19) United States
(12) Patent Application Publication
(10) Pub. No.: US 2024/0120374 A1
(43) Pub. Date: Apr. 11, 2024

(54) SEMICONDUCTOR STRUCTURE AND PREPARATION METHOD THEREOF

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/484,581

(22) Filed: Oct. 11, 2023

(30) Foreign Application Priority Data
Oct. 11, 2022 (CN) 202211242229.7

(51) Int. Cl. H01L 29/06; H01L 29/08; H01L 29/20

(52) U.S. Cl. CPC H01L 29/0661; H01L 29/0843; H01L 29/2003; H01L 29/7788

(57) ABSTRACT

Disclosed are a semiconductor structure and a preparation method thereof. The semiconductor structure comprises a first nitride semiconductor layer, a second nitride semiconductor layer formed on the first nitride semiconductor layer, and a third nitride semiconductor layer formed on the second nitride semiconductor layer with a groove penetrating through the third nitride layer. In the present disclosure, by etching the groove on the third nitride semiconductor layer of P-type doping, and then secondarily extending selectively a N-type doped source region in the groove, the sharp P-N interface formed between the third nitride semiconductor layer and the second nitride semiconductor layer can further help control the shape of the groove, reduce the on-resistance and improve the breakdown voltage of the semiconductor structure.

### CROSS-REFERENCE TO RELATED APPLICATIONS

The present application claims priority to Chinese Patent Application No. 202211242229.7, filed on Oct. 11, 2022, which is hereby incorporated by reference in its entirety.

### TECHNICAL FIELD

The present disclosure relates to the technical field of semiconductors, and specifically, to a semiconductor structure and a preparation method thereof.

### BACKGROUND

Gallium nitride (GaN) is a typical third generation wide band gap semiconductor, and of widely popularity. Its superior properties are mainly manifested in its high electron mobility and high two-dimensional electron gas (2 DEG) concentration. In addition, the material of gallium nitride (GaN) has stable chemical properties, high tolerance to high temperatures, high corrosion resistance, and have innate advantage in high frequency, high power and radiation resistance applications.

In a transverse GaN-based HEMT device, in order to obtain higher breakdown voltage, it is necessary to increase the gate-drain spacing, but this will inevitably increase the device size and on-resistance, reduce the effective current density per unit chip area and chip performance, and lead to the chip area increase and add to development cost. In order to solve the above problems, researchers have proposed a GaN-based vertical conductive semiconductor structure.

However, after many years of research, the current GaN-based vertical semiconductor structure still present problems of high on-resistance, low breakdown voltage and its working power still could not meet the requirements for some applications.

### SUMMARY

The purpose of the present disclosure is to provide a semiconductor structure and a preparation method thereof, to reduce on-resistance, improve breakdown voltage and increase working power.

According to one aspect of the present disclosure, a semiconductor structure is provided, and the semiconductor structure includes: a first nitride semiconductor layer including a first surface and a second surface being opposite to the first surface; a second nitride semiconductor layer formed on the first nitride semiconductor layer, the second nitride semiconductor layer having the same conductivity type as the first nitride semiconductor layer, and the doping concentration of the second nitride semiconductor layer being lower than the doping concentration of the first nitride semiconductor layer; a third nitride semiconductor layer formed on the second nitride semiconductor layer, the conductivity type of the third nitride semiconductor layer is opposite to the conductivity type of the second nitride semiconductor layer, the third nitride semiconductor layer including a groove and the groove penetrating through the third nitride semiconductor layer;
a source region being formed in the groove, connected with the second nitride semiconductor layer, and having the same conductivity type as the second nitride semiconductor layer.

As an alternative embodiment, the second nitride semiconductor layer includes an AlGaN insertion layer located inside or on the surface of the second nitride semiconductor layer, and the bottom of the groove exposes the AlGaN insertion layer.

As an alternative embodiment, along an epitaxial growth direction, the Al composition of the AlGaN insertion layer increases from 0 of Al composition at initial growth to the maximum value A of Al composition, and then to 0 of Al composition at the end of growth; or,
along an epitaxial growth direction, the Al composition of the AlGaN insertion layer increases from 0 of Al composition to the maximum value A of Al composition or increases from 0 of Al composition to the maximum value A of Al composition and then decreases to an intermediate value B of Al composition;
along an epitaxial growth direction, the Al composition of the AlGaN insertion layer decreases from the maximum value A of Al composition to 0 of Al composition or increases from the intermediate value B of Al composition to the maximum value A of Al composition and then decreases to 0 of Al composition.

As an alternative embodiment, along an epitaxial growth direction, the Al composition of the AlGaN insertion layer changes from the initial growth to the point of a maximum value Al composition in one or a combination of continuous increment, stepped increment or oscillatory increment;
along an epitaxial growth direction, the Al composition of the AlGaN insertion layer changes from the maximum Al composition to the end of growth in one or a combination of continuous decrement, stepped decrement or oscillating decrement.

As an alternative embodiment, the semiconductor structure further includes a passivation layer located on the surface of the third nitride semiconductor layer facing away from the second nitride semiconductor layer, the passivation layer is made of AlGaN, and the Al concentration in the AlGaN layer increases with the thickness of AlGaN layer.

As an alternative embodiment, the width of the groove along a direction from a bottom of the groove to a top of the groove is equal, linearly increasing, linearly decreasing, periodically varying, increasing first and decreasing after, stepped increasing or stepped decreasing.

As an alternative embodiment, a buffer layer is provided between the first nitride semiconductor layer and the second nitride semiconductor layer.

As an alternative embodiment, the third nitride semiconductor layer includes a first sub-layer of the third nitride semiconductor layer and a second sub-layer of the third nitride semiconductor layer, the first sub-layer and the second sub-layer are located from a bottom of the third nitride semiconductor layer to a top of the third semiconductor layer, and a doping concentration of the first sub-layer of the third nitride semiconductor layer is lower than the doping concentration of the second sub-layer of the third nitride semiconductor layer.

As an alternative embodiment, the source region includes a first sub-layer and a second sub-layer, the first sub-layer and the second sub-layer are located from the bottom of the source region to the top of the source region, and the doping concentration of the first sub-layer of the source region is lower than the doping concentration of the second sub-layer of the source region, where the height of the top surface of the first sub-layer of the source region does not exceed the height of the groove.

As an alternative embodiment, the third nitride semiconductor layer includes Al element, and the variation curve of the Al composition in the epitaxial growth direction includes one or more combinations of the following variation stages: periodic variation, increasing variation or decreasing variation, where the Al concentration has no jump at the contact interface between the third nitride semiconductor layer and the second nitride semiconductor layer.

As an alternative embodiment, the semiconductor structure further includes a source electrode, a gate electrode and a drain electrode, the source electrode is arranged on the source region, the gate electrode is arranged on the top surface of the third nitride semiconductor layer, and the drain electrode is arranged on the second surface of the first nitride semiconductor layer; or the semiconductor structure further includes:
a first electrode arranged on the source region;
a second electrode arranged on the second surface of the first nitride semiconductor layer.

According to another aspect of the present disclosure, a preparation method of the semiconductor structure is provided, and the preparation method includes:
providing a first nitride semiconductor layer;
forming a second nitride semiconductor layer covering the first nitride semiconductor layer, the conductivity type of the second nitride semiconductor layer being the same as the conductivity type of the first nitride semiconductor layer, and the doping concentration of the second nitride semiconductor layer being lower than the doping concentration of the first nitride semiconductor layer;
forming a third nitride semiconductor layer covering the second nitride semiconductor layer, where the conductivity type of the third nitride semiconductor layer is opposite to the conductivity type of the second nitride semiconductor layer;
forming a mask layer covering the third semiconductor layer;
forming a window on the mask layer, the window exposes the third semiconductor layer;
etching the third nitride semiconductor layer to form a groove, the groove penetrating through the third nitride semiconductor layer;
forming a source region by filling the groove, where the source region is connected with the second nitride semiconductor layer and has the same conductivity type as the second nitride semiconductor layer.

As an alternative embodiment, the second nitride semiconductor layer includes the AlGaN insertion layer located inside or on the surface of the second nitride semiconductor layer, and the bottom of the groove exposes the AlGaN insertion layer.

As an alternative embodiment, two-step etching the third nitride semiconductor layer to form the groove, where,
dry-etching the third nitride semiconductor layer to form the groove, stop etching right before etching the AlGaN insertion layer;
cleaning the groove;
in-situ etching the surface of the groove until the bottom of the groove exposes the AlGaN insertion layer.

As an alternative embodiment, along the epitaxial growth direction, the Al composition of the AlGaN insertion layer increases from 0 of Al composition at initial growth to the maximum value A of Al composition, and then to the 0 of Al composition at the end of growth; or along the epitaxial growth direction, the Al composition of the AlGaN insertion layer increases from 0 of Al composition to the maximum value A of Al composition or increases from 0 of Al composition to the maximum value A of Al composition and then decreases to the intermediate value B of Al composition; along the epitaxial growth direction, the Al composition of the AlGaN insertion layer decreases from the maximum value A of Al composition to 0 of Al composition or increases from the intermediate value B of Al composition to the maximum value A of Al composition and then decreases to 0 of Al composition.

As an alternative embodiment, the semiconductor structure further includes a passivation layer located on the surface of the third nitride semiconductor layer facing away from the second nitride semiconductor layer, the material of the passivation layer is AlGaN, and the Al composition in the AlGaN layer increases with the thickness of AlGaN layer.

As an alternative embodiment, the third nitride semiconductor layer is composed of Al element, and the composition variation curve of the Al composition in the epitaxial growth direction includes one or more combinations of the following variation stages: periodic variation, increasing variation or decreasing variation, where the Al composition has no jump at the contact interface between the third nitride semiconductor layer and the second nitride semiconductor layer.

As an alternative embodiment, the width of the groove along a direction from the bottom of the groove to a top of the groove is equal, linearly increasing, linearly decreasing, periodically varying, increasing first and decreasing after, stepped increasing or stepped decreasing.

As an alternative embodiment, the source region consists of a first sub-layer and a second sub-layer, the first sub-layer and the second sub-layer are located from a bottom of the source region to a top of the source region; the doping concentration of the first sub-layer of the source region is lower than the doping concentration of the second sub-layer of the source region, where the height of the upper surface of the first sub-layer of the source region does not exceed the groove.

### BRIEF DESCRIPTION OF THE DRAWINGS

FIG. 1 illustrates a schematic diagram of a semiconductor structure in embodiment 1 of the present disclosure.

FIG. 2 (a), FIG. 2 (b), FIG. 2 (c), FIG. 3 (a), FIG. 3 (b) and FIG. 3 (c) illustrate top views of the embodiment 1 of the present disclosure, in which the source region has formed.

FIG. 4 illustrates a schematic diagram of a semiconductor structure in embodiment 2 of the present disclosure.

FIG. 5 (a) illustrates a schematic structural diagram according to the second embodiment of the present disclosure, in which the mask layer has formed.

FIG. 5 (b) illustrates a structural schematic diagram of a groove formed by dry-etch process according to embodiment 2 of the present disclosure.

FIG. 5 (c) illustrates a structural schematic diagram of the groove formed by in-situ etch process according to embodiment 2 of the present disclosure, which the in-situ etch process follows the dry-etch process.

FIG. 5 (d) illustrates a structural schematic diagram of the source region formed according to the embodiment 2 of the present disclosure.

FIG. 6 (a) to FIG. 6 (d) illustrate schematic diagrams of composition variations of Al composition of AlGaN insertion layer in embodiment 1.

FIG. 7 illustrates a schematic diagram of a semiconductor structure in another implementation of embodiment 2 of the present disclosure.

FIG. 8 (a) to FIG. 8 (d) illustrate schematic diagrams of semiconductor structures in embodiment 3 of the present disclosure.

FIG. 9 illustrates schematic diagrams of semiconductor structures in embodiment 4 of the present disclosure.

FIG. 10 illustrates schematic diagrams of semiconductor structures in embodiment 5 of the present disclosure.

FIG. 11 illustrates schematic diagrams of semiconductor structures in embodiment 6 of the present disclosure.

FIG. 12 illustrates schematic diagrams of semiconductor structures in embodiment 7 of the present disclosure.

FIG. 13 illustrates schematic diagrams of semiconductor structures in embodiment 8 of the present disclosure.

### DETAILED DESCRIPTION OF THE EMBODIMENTS

Exemplary embodiments will be herein explained in detail, corresponding examples are shown in the accompanying drawings. In the following exemplary descriptions, when it comes to the different drawings, unless otherwise indicated, the same numbers in different drawings indicate the same or similar elements. The embodiments described in the following exemplary embodiments do not represent all embodiments covered by the present disclosure. On the contrary, they are only examples of devices consistent with some aspects of the disclosure as detailed in the appended claims.

The terms used in the present disclosure are only for the purpose of describing specific embodiments, and are not intended to limit the present disclosure. Unless otherwise defined, the technical terms or scientific terms used in the present disclosure shall have the ordinary meanings understood by those with ordinary skills in the field to which the present disclosure belongs. The words “first”, “second” and the like used in the present specification and claims do not indicate any order, quantity or importance, but are only used to distinguish different compositions.

The semiconductor structure of the present disclosure and the preparation method thereof, the semiconductor structure includes a first nitride semiconductor layer, a second nitride semiconductor layer formed on the first nitride semiconductor layer, and a third nitride semiconductor layer formed on the second nitride semiconductor layer with grooves penetrating through the third nitride semiconductor layer, those three nitride semiconductor layers are arranged from a bottom of the structure to a top of the device structure; and a source region formed in the groove. The semiconductor structure of the present disclosure fills semiconductor material into the etched groove. By designing the groove structure, the semiconductor structure can obtain different sizes of source region, lower on-resistance, increase on-current, avoid excessive local electric field density, optimize the electric field distribution, and thus improve the breakdown voltage.

### Embodiment 1

The embodiment 1 of the present disclosure provides a semiconductor structure.

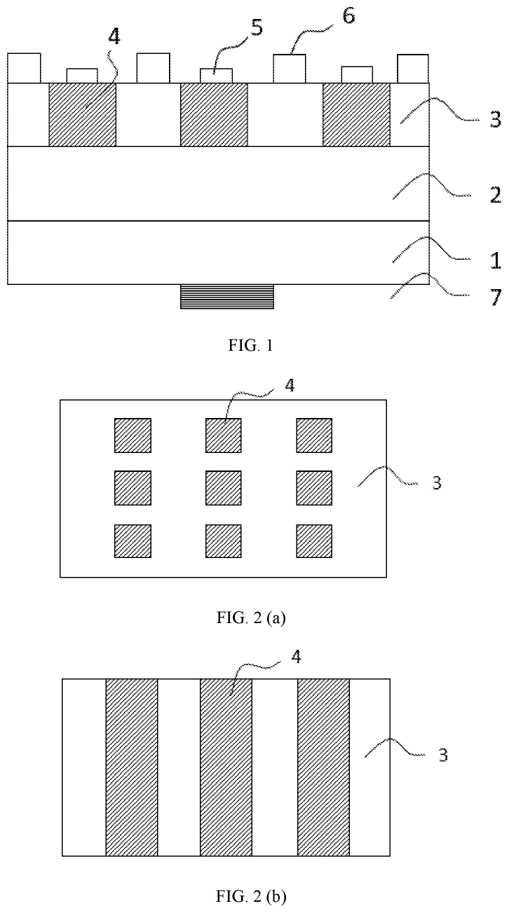

FIG. 1 is a schematic diagram of a cross-section of the semiconductor structure 100 according to the first embodiment of the present disclosure.

Referring to FIG. 1, the semiconductor structure 100 includes:
a first nitride semiconductor layer 1, a second nitride semiconductor layer 2, a third nitride semiconductor layer 3, and a source region 4, which are arranged from a bottom of the semiconductor device to a top of the semiconductor device. The first nitride semiconductor layer 1 including a first face and a second surface being opposite to the first face, the second nitride semiconductor layer 2 formed on the first nitride semiconductor layer 1, the second nitride semiconductor layer 2 having the same conductivity type as the first nitride semiconductor layer 1, and the doping concentration of the second nitride semiconductor layer 2 being lower than the doping concentration of the first nitride semiconductor layer 1; the third nitride semiconductor layer 3 formed on the second nitride semiconductor layer 2, the conductivity type of the third nitride semiconductor layer 3 is opposite to the conductivity type of the second nitride semiconductor layer 2, and a groove 30 penetrating through the third nitride semiconductor layer; the source region 4 formed in the groove 30, and having the same conductivity type as the second nitride semiconductor layer 2;
a source electrode 5, a gate electrode 6 and a drain electrode 7, the source electrode 5 is arranged on the source region 4, the gate electrode 6 is arranged on the top surface of the third nitride semiconductor layer 3, and the drain electrode 7 is arranged on the second surface of the first nitride semiconductor layer 1.

In this embodiment, the semiconductor structure 100 is a junction field effect transistor (JFET).

The semiconductor structure 100 is described in detail below.

The materials used for the first nitride semiconductor layer 1, the second nitride semiconductor layer 2, the third nitride semiconductor layer 3 and the source region 4 could all be of GaN-based, for example, all of them can be GaN.

In this embodiment, the conductivity type of the first nitride semiconductor layer 1, the second nitride semiconductor layer 2 and the source region 4 are N-type. Where the N-type doping ions can be at least one of the followings: Si-ion, Ge-ion, Sn-ion, Se-ion or Te-ion. The conductivity type of the third nitride semiconductor layer 3 is P-type, where the P-type doping ions can be at least one of Mg ions, Zn ions, Ca ions, Sr ions or Ba ions. That being said, the junction field effect transistor (JFET) is N-channel based device. Among them, the N-type dopant concentration in the first nitride semiconductor layer 1 is large, thus the first nitride semiconductor layer is heavily N-doped while the second nitride semiconductor layer is lightly N-doped. The doping ion concentration in the first nitride semiconductor layer 1 can be above the order of 10¹⁸/cm³, the doping ion concentration in the second nitride semiconductor layer 2 can be below the order of 10¹⁸/cm³. The first nitride semiconductor layer 1, the second nitride semiconductor layer 2 or the third nitride semiconductor layer 3 may have a single layer structure or a laminated multilayer structure, and the material of each layer can be GaN, AlGaN or AlInGaN, or a mixture of at least two of the above materials.

In other embodiments, the conductivity types of the first nitride semiconductor layer 1, the second nitride semiconductor layer 2 and the source region 4 are P-type, and the conductivity type of the third nitride semiconductor layer 3 is N-type. In other words, the junction field effect transistor (JFET) is a P-type channel.

The first surface and the second surface can be two opposite surfaces in the thickness direction of the first nitride semiconductor layer 1.

The materials of the source electrode 5, the gate electrode 6 and the drain electrode 7 can be metals, such as Ti/Al/Ni/Au, Ni/Au, etc. A schottky contact can be formed between the gate electrode 6 and the third nitride semiconductor layer 3, and an ohmic contact can be formed between the source electrode 5 and the source region 4, the drain electrode 7 and the second surface of the first nitride semiconductor layer 1.

In a semiconductor structure of the embodiment 100 of the present disclosure, a groove 30 is etched through the P-type doped third nitride semiconductor layer 3, a selective secondary N-type doped source region 4 is epitaxially extended in the groove 30. Contrary to the P-N interface from the conventional ion implantation method, the P-N interface formed between the third nitride semiconductor layer and the second nitride semiconductor layer is more clear. It also helps control the shape of the grooves, reduces the on-resistance and improving the breakdown voltage of the conductor structure 100.

The preparation method of the semiconductor structure 100 may include steps S110-S170, in which:
S110, providing a first nitride semiconductor layer 1, where the first nitride semiconductor layer 1 includes a first surface and a second surface being opposite to the first surface;
S120, forming a second nitride semiconductor layer 2 covering the first surface of the first nitride semiconductor layer 1, where the second nitride semiconductor layer 2 has the same conductivity type as the first nitride semiconductor layer 1, and the doping concentration of the second nitride semiconductor layer 2 being lower than the doping concentration of the first nitride semiconductor layer 1;
S130, forming a third nitride semiconductor layer 3 covering the second nitride semiconductor layer 2, where the conductivity type of the third nitride semiconductor layer 3 is opposite to the conductivity type of the second nitride semiconductor layer 2;
S140, forming a mask layer 8 covering the third nitride semiconductor layer 3, and forming a window 801 on the mask layer 8, the window 801 exposes the third nitride semiconductor layer 3;
S150, etching the third nitride semiconductor layer 3 to form a groove 30, penetrating through the third nitride semiconductor layer;
S160, forming a source region 4 filling the recess 30, where the source region 4 connected with the second nitride semiconductor layer 2, and the conductivity type of the source region 4 is being the same as the conductivity type of the second nitride semiconductor layer 2;
S170, forming a source electrode 5, a gate electrode 6 and a drain electrode 7, where the source electrode 5 is disposed on the source region 4, the gate electrode 6 is disposed on the top surface of the third nitride semiconductor layer 3, and the drain electrode 7 is disposed on the second surface of the first nitride semiconductor layer 1.

The preparation method of the semiconductor structure provided by the embodiment of the present disclosure belongs to the same inventive concept as the semiconductor structure, and the description of relevant details and beneficial effects can be referred to each other, thus specific details will not be repeated here.

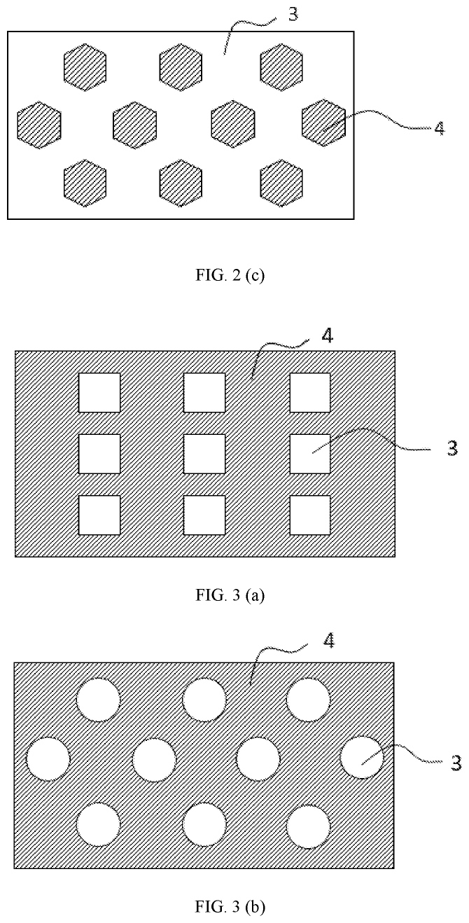

FIG. 2 (a), FIG. 2 (b) and FIG. 2 (c) are top views of the first embodiment of the present disclosure, the source region has formed in the first embodiment; and there can be a multiple of the grooves 30 and the plurality of grooves 30 are arranged at intervals. The horizontal projection of the groove 30 can be circular. On the other hand, the horizontal projection of the groove 30 can also be one or more combinations of other shapes such as bar, rectangle, hexagon, triangle, etc. As shown in FIG. 2 (a), a plurality of horizontally projected rectangular grooves 30 can be distributed in a rectangular shape. As an example, the horizontal projection of the groove 30 is in a shape of the bar as shown in FIG. 2 (b), a plurality of grooves 30 can be arranged in parallel and distributed at intervals; as shown in FIG. 2 (b), a plurality of horizontally projected hexagonal grooves 30 can be arranged in a hexagonal manner, and the source regions 4 are filled in the grooves 30.

FIG. 3 (a), FIG. 3 (b) and FIG. 3 (c) are top views of the first embodiment of the present disclosure after source region being formed inside the first embodiment. The planar projection shape of the groove 30 is a net structure, as shown in FIGS. 3 (a), 3 (b) and 3 (c), and the mesh shape of the net structure is one or more combinations of circles, squares, hexagons or triangles. The source region 4 is epitaxially grown in the mesh-shaped groove 30, and the meshes correspond to the unetched areas of the third nitride semiconductor layer 3, and the horizontal projections of the unetched areas of the third nitride semiconductor layer 3 are square, circular, hexagonal, etc.

### Embodiment 2

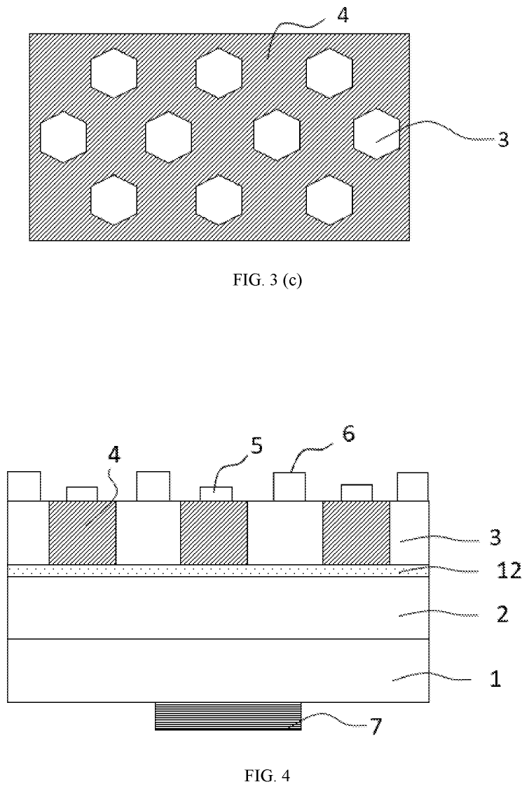

FIG. 4 is a schematic diagram of a semiconductor structure 200 according to the second embodiment of the present disclosure. The semiconductor structure and its preparation method of embodiment 2 of the present disclosure are roughly the same as those of embodiment 1 of the present disclosure, with the difference that the second nitride semiconductor layer 2 contains the AlGaN insertion layer 12 located on the surface of the second nitride semiconductor layer 2.

Correspondingly, the only difference between the preparation method of the semiconductor structure 200 of embodiment 2 and the preparation method of embodiment 1 lies in that the second nitride semiconductor layer 2 formed in step S120 contains the AlGaN insertion layer 12 located on the surface of the second nitride semiconductor layer 2.

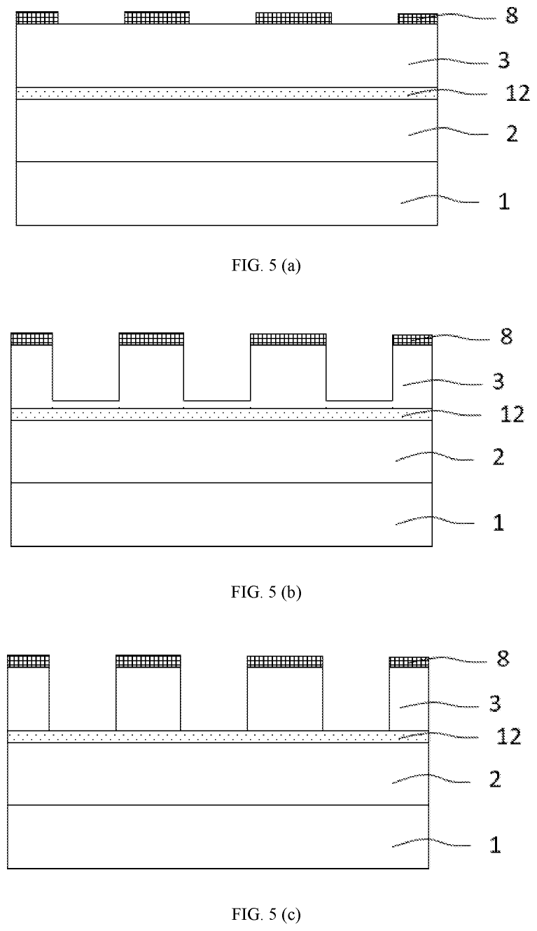

FIG. 5 (a) illustrates a schematic structural diagram according to the second embodiment of the present disclosure after the mask layer has been formed. FIG. 5 (b) illustrates a structural schematic diagram of a groove formed by dry-etch process according to embodiment 2 of the present disclosure. FIG. 5 (c) illustrates a structural schematic diagram of the groove formed by two-step etch process according to embodiment 2 of the present disclosure, the two-step etch process consists dry etch process followed by in-situ etch process. FIG. 5 (d) illustrates a structural schematic diagram of the source region formed according to the embodiment 2 of the present disclosure.

Specifically, step S140 can include: forming a mask layer 8 covering the third nitride semiconductor layer 3, as shown in FIG. 5 (a).

The material of this mask layer 8 can be an insulating material, such as SiO2, etc. The mask layer 8 can be prepared by vapor deposition, but the embodiment of the present disclosure is not specifically limited to this.

A window 801 is formed on the mask layer 8, which exposes the third nitride semiconductor layer 3. The window 801 can be formed by etching.

Specifically, step S150 can include:
S151, dry-etching the third nitride semiconductor layer 3 to form a groove 30, and stop etching right before etching the AlGaN insertion layer;
S152, cleaning the groove 30;
S153, in-situ etching the surface of the groove 30 until the bottom of the groove exposes the AlGaN insertion layer.

As shown in FIG. 5 (b), utilizing the mask layer 8 formed with the window 801 as a mask layer, dry-etch the third nitride semiconductor layer 3 to form a groove 30, stop etch process right before etching the AlGaN insertion layer 12. During the dry-etch step, there is usually etch damage from the etch process inside the groove 30.

As shown in FIG. 5 (c), the semiconductor structure 100 is transferred into an epitaxial deposition machine, to continue the in-situ etch process to the groove 30. The gas used in the in-situ etch process is H₂, or H₂ and HCl, or a Cl-based gas source TBCl.

Specifically, S160 may include forming a source region 4 filling the groove 30, as shown in FIG. 5 (d).

In the disclosure, the third nitride semiconductor layer is being etched by a two-step etch process consisting dry-etch and in-situ etch process, shortly after the in-situ etch process, the source region material is secondarily epitaxially extended; on the one hand, the in-situ etch process provides a secondary etch process for the groove, restores the damage to the groove caused by conventional etching, and ensures the growth quality of GaN material of source region in the subsequent secondary epitaxial extension; on the other hand, the in-situ etch process and the subsequent epitaxial extension process are carried out in the same extension machine, carrying out both process in the same extension machine can greatly shorten the processing time and reduce the contamination sources. Optionally, the time interval between in-situ etching the groove 30 and growing the source region 4 by the subsequent epitaxial extension process is less than 1 h.

The preparation method of the semiconductor structure provided by the embodiment of the present disclosure belongs to the same inventive concept as the semiconductor structure, and the description of relevant details and beneficial effects can be referred to each other, so they will not be repeated here.

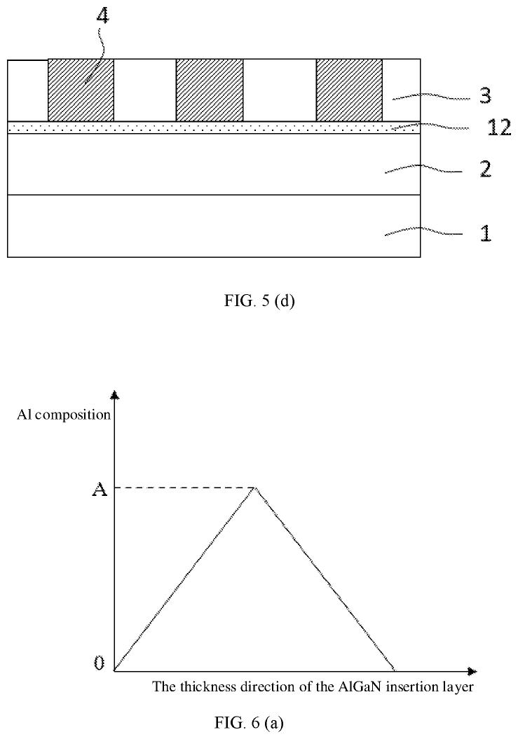

FIG. 6 (a) to FIG. 6 (d) illustrate schematic diagrams of composition variations of Al element of AlGaN insertion layer in embodiment 1. The second nitride semiconductor layer 2 according to the first embodiment of the present disclosure has a laminated structure and includes an AlGaN insertion layer. Along the epitaxial extension growth direction, the Al composition of the AlGaN insertion layer increases from 0 of Al composition at initial growth to the maximum value A of Al composition, and then to the 0 of Al composition at the end of growth. Along the epitaxial extension growth direction, the Al composition of the AlGaN insertion layer varies from the initial growth to the point of the maximum Al composition in one or a combination of continuous increment, stepped increment or oscillatory increment. Along the epitaxial extension growth direction, the Al composition of the AlGaN insertion layer changes from the maximum Al composition to the end of growth in one or a combination of continuous decrement, stepped decrement or oscillating decrement.

As shown in FIG. 6 (a), along the epitaxial extension growth direction, the Al composition of the AlGaN insertion layer 12 varies from the initial growth to the point of the maximum Al composition in a continuous increment followed by a continuous decrement terminating at 0 of Al composition.

As shown in FIG. 6 (b), along the epitaxial extension growth direction, the Al composition of the AlGaN insertion layer 12 varies from the initial growth to the point of the maximum Al composition in a continuous increment terminating with the maximum value A of Al composition, and the value is then held for a period of time. In other words, the maximum value A of Al composition of the AlGaN insertion layer 12 keeps to a certain thickness, and then the Al composition decreases continuously until the Al composition becomes 0.

As shown in FIG. 6 (c), along the epitaxial extension growth direction, the Al composition of the AlGaN insertion layer 12 varies from the initial growth to the point of the maximum Al composition in a stepped increment followed by a stepped decrement terminating with 0 of Al composition.

As shown in FIG. 6 (d), the Al composition of the AlGaN insertion layer 12 varies from the initial growth to the point of the maximum Al composition in an oscillatory increment followed by an oscillatory decrement terminating with 0 of Al composition.

Alternatively, along the epitaxial extension growth direction, the Al composition of the AlGaN insertion layer increases from 0 of Al composition to the maximum value A of Al composition or increases from 0 of Al composition to the maximum value A of Al composition and then decreases to the intermediate value B of Al composition.

Alternatively, along the epitaxial extension growth direction, the Al composition of the AlGaN insertion layer decreases from the maximum value A of Al composition to 0 of Al composition or increases from the intermediate value B of Al composition to the maximum value A of Al composition and then decreases to 0 of Al composition.

In this embodiment, the concentration with maximum Al composition is around the middle position inside the AlGaN insertion layer 12. In other embodiments of this embodiment, the concentration with maximum Al composition inside AlGaN insertion layer 12 is close to the side of the AlGaN insertion layer 12 away from the second nitride semiconductor layer 2, in other words, close to the upper surface of the AlGaN insertion layer 12.

In the present disclosure, the AlGaN insertion layer 12 with Al composition increasing first and decreasing after, is arranged between the interface of the second nitride semiconductor layer and the third nitride semiconductor layer. The AlGaN insertion layer, on the one hand, serves as an etch stop layer to ensure the etching accuracy for the third nitride semiconductor layer; on the other hand, with the design of the concentration variation pattern of Al composition of the AlGaN intercalation layer, the nitride semiconductor layers (in contact with the upper side, lower side, or both the upper and the lower sides of the AlGaN insertion layer) have no jump change of Al composition, thus a smooth transition in material composition, reduced growth dislocation defects, and the material quality of the nitride semiconductor layer is guaranteed.

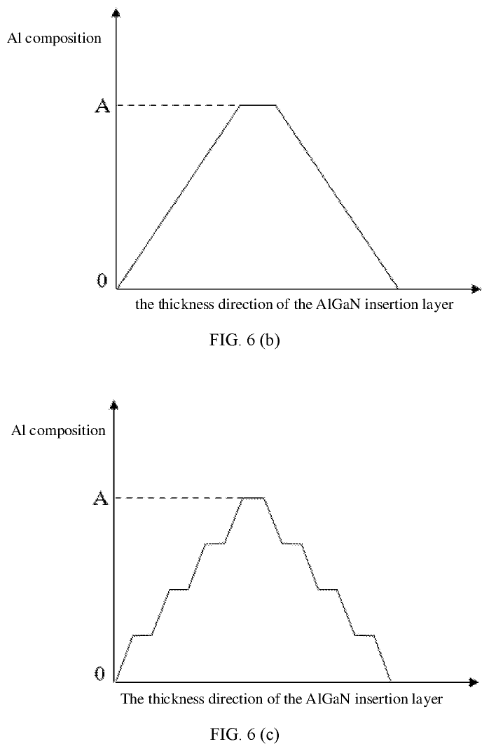

Since the AlGaN insertion layer 12 is not easily decomposed at high temperature, in-situ etching will not penetrate through the AlGaN insertion layer 12, thus the depth of the groove 30 can be accurately controlled. Optionally, in other embodiments of the second embodiment of the present disclosure, as shown in FIG. 7, the AlGaN insertion layer 12 is located inside rather than on the surface of the second nitride semiconductor layer 2. Hence, when there is a specific design requirement for the depth of the groove 30, the design requirement can be met by controlling the specific position of the AlGaN insertion layer 12 inside the second nitride semiconductor layer 2 and thus controlling the precise depth of the groove 30.

### Embodiment 3

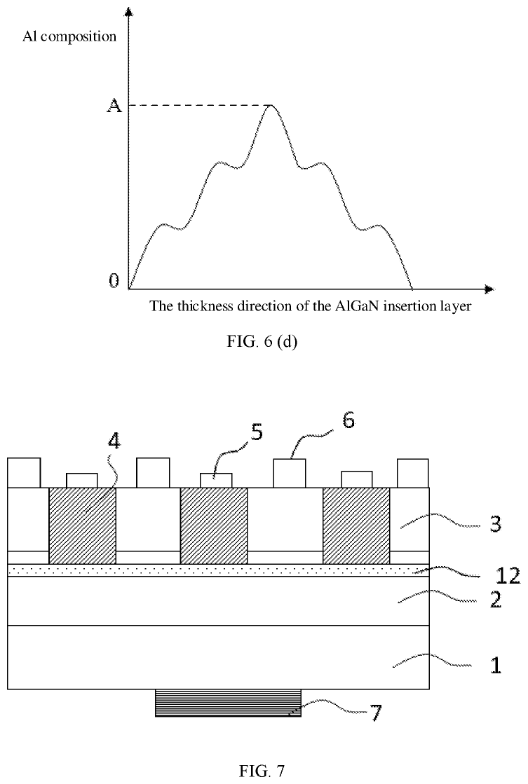

FIG. 8 (a), FIG. 8 (b), FIG. 8 (c) and FIG. 8 (d) are schematic diagrams of a semiconductor structure 300 prepared according to the third embodiment of the present disclosure. The semiconductor structure and its preparation method of embodiment 3 of the present disclosure are roughly the same as the semiconductor structure and their preparation methods of embodiment 1 or embodiment 2 of the present disclosure. The difference is that, the width of the groove 30 along a direction from a bottom of the groove to a top of the groove of the semiconductor structure in the first embodiment or the second embodiment of the present disclosure is equal. However, the width of the groove 30 of the semiconductor structure 300 of the third embodiment of the present disclosure is linearly increasing, linearly decreasing, stepped increasing stepped decreasing, periodically varying, or increasing first and decreasing after; accordingly, the width dimension of the source region 4 filled in the groove 30 is linearly increasing, linearly decreasing, stepped increasing stepped decreasing, periodically varying, or increasing first and decreasing after. By changing the width and shape of the source region 4, the contact area between the source region 4 and the third nitride semiconductor layer 3 is increased, as a result, the on-resistance of the semiconductor structure 300 can be further reduced. By designing the shape of the source region 4, a high electric field density in some areas can be avoided, the electric field distribution can be optimized, and the breakdown voltage can be increased.

Since the width of the groove is periodically varying, linearly increasing, linearly decreasing, increasing first and decreasing after, and the like, in the groove, the contact interface between the N-type source region and the side of the P-type third nitride semiconductor layer varies periodically or forms an inclined surface. on the one hand, with the controlling of the shape of the contact interface between the P-N junction, the reverse breakdown voltage can be effectively increased; on the other hand, during the on state, due to the periodic curved surface or inclined surface of the contact interface, the electrons flowing from the source region to the drain region can flow downward while dispersing to both side, which increases the moving path of the electrons, and thus further reduces the on-resistance of the semiconductor structure.

### Embodiment 4

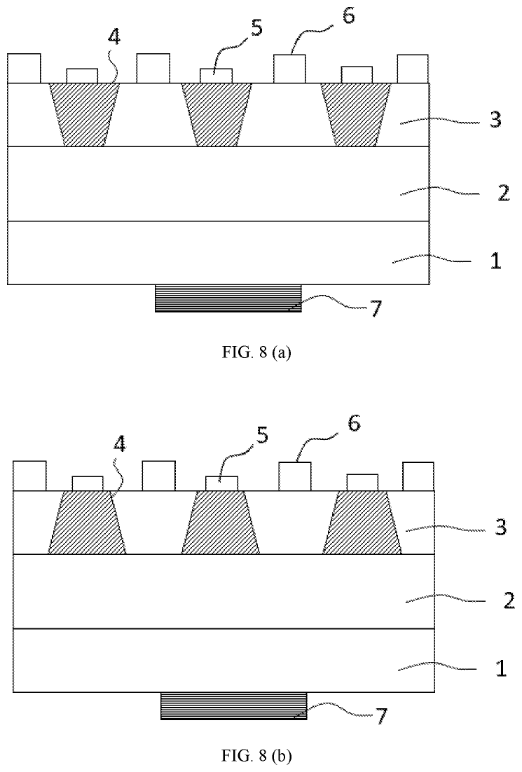

FIG. 9 illustrates schematic diagrams of semiconductor structures 400 in embodiment 4 of the present disclosure. The semiconductor structure and its preparation method of embodiment 4 of the present disclosure are roughly the same as the semiconductor structure and its preparation method of embodiment 1 of the present disclosure. The difference is that, before S120, the preparation method further includes forming a buffer layer 9 covering the first surface of the first nitride semiconductor layer 1, and the second nitride semiconductor layer 2 is formed on the side of the buffer layer 9 facing away from the first nitride semiconductor layer 1.

The conductivity type of the buffer layer 9 is the same as the conductivity type of the first nitride semiconductor layer 1. For example, the buffer layer 9 is an N-type buffer layer 9. The material of the buffer layer 9 can be GaN, AlGaN or AlInGaN, or other semiconductor materials Ga and N based, or a mixture of at least two of the above materials. A buffer layer groove 901 is formed on the surface of the buffer layer 9 facing away from the first nitride semiconductor layer 1, the buffer layer groove 901 being corresponding to the first groove 101. The buffer layer 9 can be formed by epitaxial growth, but the embodiment of the present disclosure is not particularly limited to this. The buffer layer 9 can form a buffer layer groove 901 in a conformal way during the epitaxial growth.

The conductivity type of the buffer layer 9 is opposite to the conductivity type of the first semiconductor 1. For example, the buffer layer 9 is a P-type buffer layer, which is supplemented by electrons in the first semiconductor 1 and the second semiconductor to form a depletion layer; The buffer layer 9 can be described as an alloy layer or a superlattice structure layer, and serves as a barrier layer for impurities and defects.

It should be noted that the buffer layer 9 may have a single layer structure or a laminated structure.

### Embodiment 5

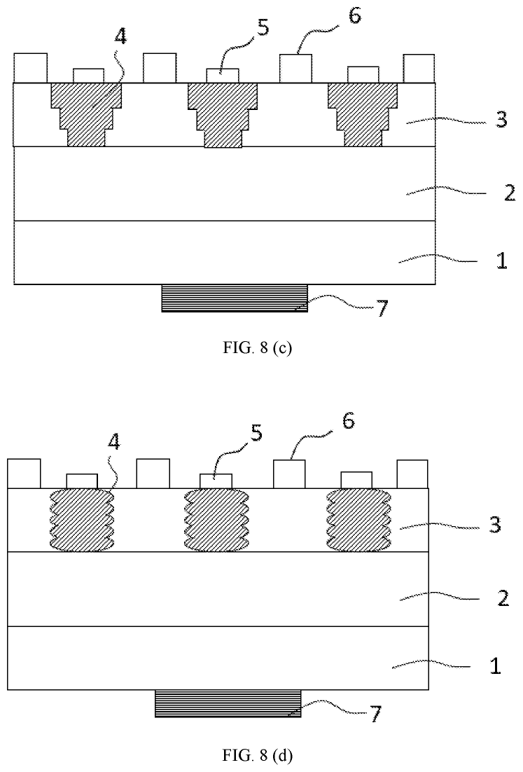

FIG. 10 illustrates schematic diagrams of semiconductor structures 500 in embodiment 5 of the present disclosure. The semiconductor structure and its preparation method of Embodiment 5 of the present disclosure are roughly the same as the semiconductor structure and the preparation method of any one of Embodiments 1 to 4 of the present disclosure. The difference is that, the third nitride semiconductor layer 3 includes a first sub-layer 31 and a second sub-layer 32 of the third nitride semiconductor layer arranging from the bottom of the third nitride semiconductor structure to the top of the third nitride semiconductor structure, and the doping concentration of the first sub-layer 31 of the third nitride semiconductor layer is smaller than the doping concentration of the second sub-layer 32 of the third nitride semiconductor layer. Consequently, the breakdown voltage of the vertical conduction structure 500 can be increased, the doping concentration of the first sub-layer 31 of the third nitride semiconductor layer is small, the epitaxial growth quality of the second sub-layer 32 of the third nitride semiconductor layer can be improved, and thus the dislocation defects can be reduced.

### Embodiment 6

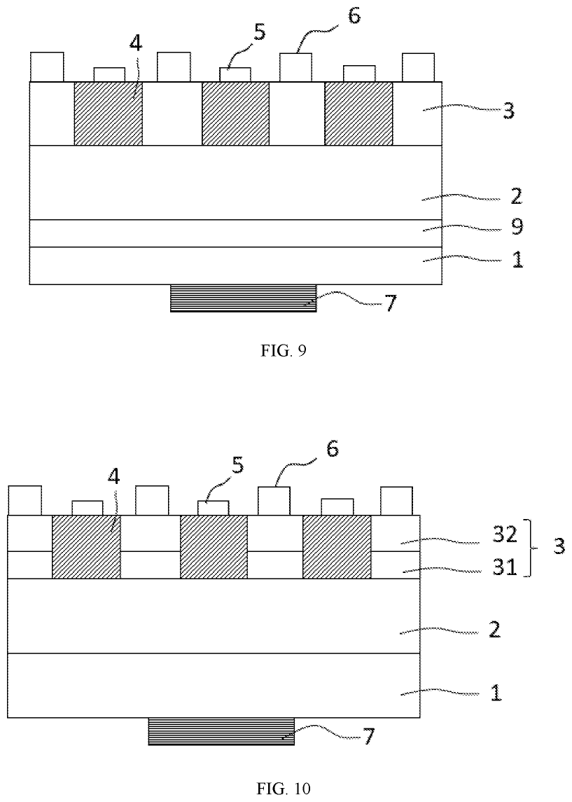

FIG. 11 illustrates schematic diagrams of semiconductor structures 600 in embodiment 6 of the present disclosure. The semiconductor structure and its preparation method of embodiment 6 of the present disclosure are roughly the same as the semiconductor structure and the preparation method of any one of embodiments 1 to 5 of the present disclosure. The difference is that, the source region 4 includes a first sub-layer 41 and a second sub-layer 42 arranging from the bottom of the source region 4 to the top of the source region 4. The doping concentration of the first sub-layer 41 of the source region is smaller than the doping concentration of the second sub-layer 42 of the source region. Where, the second sublayer 42 of the source region is parallel with the upper surface of the third nitride semiconductor layer 3, the source region 4 of the semiconductor structure 600 of the sixth embodiment adopts a layered structure, the second sub-layer 42 of the source region is made of heavily doped material, which is effectively reducing the contact resistance between the source electrode 5 and the source region 4. At the same time, the first sub-layer 41 of the source region 4 is in contact with the second nitride semiconductor layer 2 arranging below the first sub-layer 41 of source region 4, the first sub-layer 41 of source region 4 can thus serve as a transition layer. In other embodiments of the sixth embodiment, the height of the upper surface of the first sub-layer 41 of the source region does not exceed the groove 30. The upper surface of the first sub-layer 41 of the source region may be parallel with the upper surface of the third nitride semiconductor layer 3 or lower than the opening position of the groove 30. The heavily doped second sub-layer 42 of the source region can exceed the opening position of the groove 30 to form the outside of the groove 30, or the top surface of the heavily doped second sub-layer 42 of the source region and the top surface of the third nitride semiconductor layer 3 can be in parallel.

### Embodiment 7

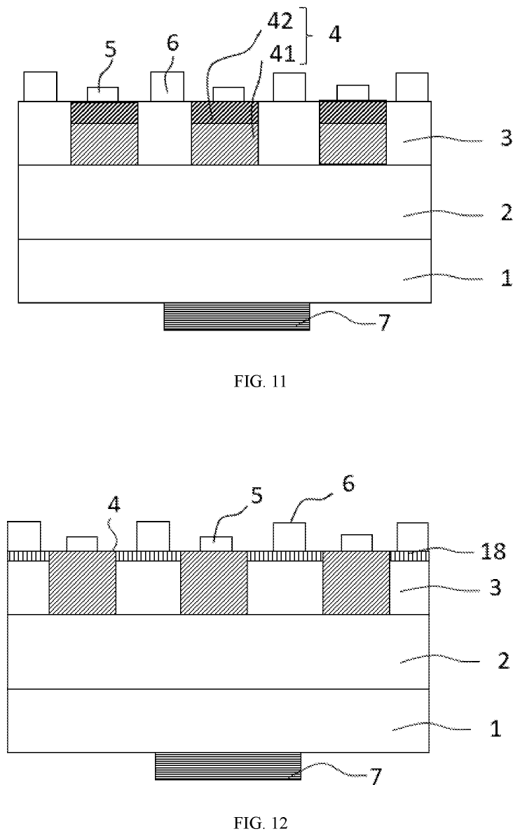

FIG. 12 illustrates schematic diagrams of semiconductor structures 700 in embodiment 7 of the present disclosure. The semiconductor structure and its preparation method of embodiment 7 of the present disclosure are roughly the same as the semiconductor structure and the preparation method of embodiments 1 to 6 of the present disclosure. The difference is that, the semiconductor structure further includes a passivation layer 18. The passivation layer 18 is located on the surface of the third nitride semiconductor layer 3 facing away from the second nitride semiconductor layer 2, the passivation layer 18 is made of AlGaN, and the Al composition in the AlGaN layer increases with the thickness of AlGaN layer. There is no Al composition jump between the passivation layer 18 and the underlying third nitride semiconductor, which ensures the crystal growth quality. On the one hand, the passivation layer 18 can reduce the leakage current from the semiconductor structure to the electrode area; on the other hand, the passivation layer 18 can prevent the ions in the lower structure layer from migrating to the surface of the semiconductor structure and thus protect the upper layer structure, such as preventing the diffusion of Si atom and Mg atom, and their impacts on the semiconductor structure.

### Embodiment 8

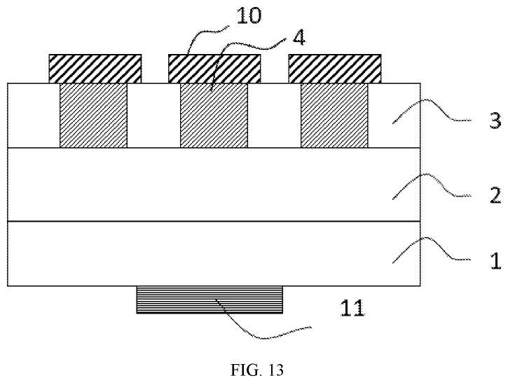

FIG. 13 illustrates schematic diagrams of semiconductor structures 800 in embodiment 8 of the present disclosure. The semiconductor structure and its preparation method of embodiment 8 of the present disclosure are roughly the same as semiconductor structure and the preparation method of embodiment 1 or embodiment 2 of the present disclosure. The difference is that, a first electrode 10 is formed on the top surface of the source region 4 and is in contact with the third nitride semiconductor layer 3; a second electrode 11 is formed on the second surface of the first nitride semiconductor layer 1. Specifically, the first electrode 10 is an anode and the second electrode 11 is a cathode, and the anode simultaneously is in contact with the second semiconductor 2 and the third nitride semiconductor layer 3. In other words, the semiconductor structure 800 of embodiment 8 is a Schottky diode.

### Embodiment 9

The semiconductor structure and its preparation method of embodiment 9 of the present disclosure are roughly the same as the semiconductor structure and the preparation method of embodiments 1 to 8 of the present disclosure. The difference is that, the third nitride semiconductor layer contains Al element, and the composition variation curve of the Al composition in the epitaxial growth direction includes one or more combinations of the following variation stages: periodic variation, increasing variation or decreasing variation, where the Al composition has no jump at the contact interface between the third nitride semiconductor layer and the second nitride semiconductor layer. By controlling of the composition variation of the Al composition of the third nitride semiconductor layer, the present disclosure can locally modulate the carrier concentration in the source region. After device optimization, the local modulation of carrier concentration can serve the following functions: during the off condition, the varying carrier concentration of the Al composition of the third nitride semiconductor layer can increase the width of the depletion layer, lower the peak of the electric field, and thus increase the breakdown voltage; during the on condition, the structure has the characteristic of reducing the on resistance, this characteristic of lowering on-resistance enables a small voltage drop during the on state when there is a high current density. As a result, the system's utilization of energy conversion efficiency is largely increased.

The above mentioned are only preferred embodiments of the present disclosure, and do not limit the present disclosure in any way. Although the disclosure has been disclosed in a preferred embodiment, it is not meant to limit the disclosure. Anyone familiar with the art can make some changes or modifications to the equivalent embodiments by using the technical content disclosed above without departing from the scope of the technical scheme of the present disclosure. However, without departing from the content of the technical scheme of the present disclosure, any simple modifications, equivalent changes and modifications made to the above embodiments according to the technical essence of the present disclosure are still within the scope of the technical scheme of the present disclosure.

What is claimed is:

1. A semiconductor structure, comprising:
a first nitride semiconductor layer comprising a first surface and a second surface being opposite to the first surface;
a second nitride semiconductor layer formed on the first nitride semiconductor layer, a conductivity type of the second nitride semiconductor layer and a conductivity type of the first nitride semiconductor layer being the same, and a doping concentration of the second nitride semiconductor layer being lower than a doping concentration of the first nitride semiconductor layer;
a third nitride semiconductor layer formed on the second nitride semiconductor layer, a conductivity type of the third nitride semiconductor layer being opposite to the doping concentration of the second nitride semiconductor layer, the third nitride semiconductor layer comprising a groove, and the groove penetrating the third nitride semiconductor layer; and
a source region formed in the groove, and a conductivity type of the source region and the conductivity type of the second nitride semiconductor layer being same.

2. The semiconductor structure according to claim 1, wherein,
the second nitride semiconductor layer comprises an AlGaN insertion layer located inside or on a surface of the second nitride semiconductor layer, and a bottom of the groove exposes the AlGaN insertion layer.

3. The semiconductor structure according to claim 2, wherein,
along an epitaxial growth direction, the Al composition of the AlGaN insertion layer increases from 0 of Al composition at initial growth to a maximum value of Al composition, and then to 0 of Al composition at the end of growth; or
along an epitaxial growth direction, the Al composition of the AlGaN insertion layer increases from 0 of Al composition to the maximum value of Al composition or increases from 0 of Al composition to the maximum value of Al composition and then decreases to an intermediate value of Al composition; or
along an epitaxial growth direction, the Al composition of the AlGaN insertion layer decreases from the maximum value to 0 of Al composition or increases from the intermediate value to the maximum value of Al composition and then decreases to 0 of Al composition.

4. The semiconductor structure according to claim 3, wherein, along the epitaxial growth direction, the Al composition of the AlGaN insertion layer changes from the initial growth to a point of a maximum Al composition in one or a combination of continuous increment, stepped increment or oscillatory increment; and
along the epitaxial growth direction, the Al composition of the AlGaN insertion layer changes from the maximum Al composition to the end of growth in one or a combination of continuous decrement, stepped decrement or oscillating decrement.

5. The semiconductor structure according to claim 1, wherein, the semiconductor structure further comprises a passivation layer, the passivation layer is located on a surface of the third nitride semiconductor layer away from the second nitride semiconductor layer, and the passivation layer is made of AlGaN, and Al concentration in the AlGaN layer increases with thickness of the AlGaN layer.

6. The semiconductor structure according to claim 1, wherein, width of the groove along a direction from a bottom of the groove to a top of the groove is equal, linearly increasing, linearly decreasing, periodically varying, increasing first and decreasing after, stepped increasing or stepped decreasing.

7. The semiconductor structure according to claim 1, wherein, a buffer layer is located between the first nitride semiconductor layer and the second nitride semiconductor layer.

8. The semiconductor structure according to claim 1, wherein, the third nitride semiconductor layer comprises a first sub-layer of the third nitride semiconductor layer and a second sub-layer of the third nitride semiconductor layer,
the first sub-layer and the second sub-layer are located from a bottom of the third nitride semiconductor layer to a top of the third nitride semiconductor layer, and
a doping concentration of the first sub-layer of the third nitride semiconductor layer is lower than a doping concentration of the second sub-layer of the third nitride semiconductor layer.

9. The semiconductor structure according to claim 1, wherein, from bottom-up direction, the source region comprises a first sub-layer and a second sub-layer, a doping concentration of the first sub-layer of the source region is lower than a doping concentration of the second sub-layer of the source region, and the top of the upper surface of the first sub-layer of the source region does not exceed the groove.

10. The semiconductor structure according to claim 1, wherein, the third nitride semiconductor layer comprises Al element, and a composition curve of the Al composition in epitaxial direction comprises one or more combinations of the following variation stages: periodic variation, increasing variation and decreasing variation, and
the Al composition has no jump at a contact interface between the third nitride semiconductor layer and the second nitride semiconductor layer.

11. The semiconductor structure according to claim 1, further comprising:
a source electrode, a gate electrode and a drain electrode, the source electrode being arranged on the source region, the gate electrode being arranged on the top surface of the third nitride semiconductor layer, and the drain electrode being arranged on the second surface of the first nitride semiconductor layer; or
a first electrode arranged on the source region, and a second electrode arranged on the second surface of the first nitride semiconductor layer.

12. A preparation method of a semiconductor structure, comprising:
providing a first nitride semiconductor layer;
forming a second nitride semiconductor layer covering the first nitride semiconductor layer, a conductivity type of the second nitride semiconductor layer and a conductivity type of the first nitride semiconductor layer being same, and doping concentration of the second nitride semiconductor layer being lower than doping concentration of the first nitride semiconductor layer;
forming a third nitride semiconductor layer covering the second nitride semiconductor layer, wherein a conductivity type of the third nitride semiconductor layer is opposite to the conductivity type of the second nitride semiconductor layer;
forming a mask layer covering the third semiconductor layer;
forming an opening on the mask layer, the opening exposes the third semiconductor layer;
etching the third nitride semiconductor layer to form a groove, the groove penetrating the third nitride semiconductor layer; and
forming a source region after filling the groove, wherein the source region is connected with the second nitride semiconductor layer, and a conductivity type of the source region and the conductivity type of the second nitride semiconductor layer being same.

13. The preparation method of the semiconductor structure according to claim 12, wherein, the second nitride semiconductor layer comprises the AlGaN insertion layer, the AlGaN insertion layer is located inside or on a surface of the second nitride semiconductor layer, and a bottom of the groove exposes the AlGaN insertion layer.

14. The preparation method of the semiconductor structure according to claim 13, wherein, the groove is formed by two-steps etching the third nitride semiconductor layer as follows:
dry-etching the third nitride semiconductor layer to form the groove, stop etch process right before etching the AlGaN insertion layer;
cleaning the groove; and
in-situ etching the surface of the groove until the bottom of the groove exposing the AlGaN insertion layer.

15. The preparation method of the semiconductor structure according to claim 13, wherein,
along an epitaxial growth direction, Al composition of the AlGaN insertion layer increases from 0 at initial growth to a maximum value of Al composition, and then to 0 of Al composition at the end of growth; or
along the epitaxial growth direction, the Al composition of the AlGaN insertion layer increases from 0 to the maximum value of Al composition or increases from 0 to the maximum value of Al composition and then decreases to an intermediate value of Al composition; or
along the epitaxial growth direction, the Al composition of the AlGaN insertion layer decreases from the maximum value to 0 of Al composition or increases from the intermediate value to the maximum value of Al composition and then decreases to 0 of Al composition.

16. The preparation method of the semiconductor structure according to claim 15, wherein, along the epitaxial growth direction, the Al composition of the AlGaN insertion layer changes from the initial growth to a point of a maximum Al composition in one or a combination of continuous increment, stepped increment or oscillatory increment; and
along the epitaxial growth direction, the Al composition of the AlGaN insertion layer changes from the maximum Al composition to the end of growth in one or a combination of continuous decrement, stepped decrement or oscillating decrement.

17. The preparation method of the semiconductor structure according to claim 12, wherein,
the third nitride semiconductor layer is composed of Al element, and the composition curve of the Al composition in epitaxial direction comprises one or more combinations of the following variation stages: periodic variation, increasing variation and decreasing variation,
wherein the Al composition has no jump at the contact interface between the third nitride semiconductor layer and the second nitride semiconductor layer.

18. The preparation method of the semiconductor structure according to claim 12, wherein, from bottom-up direction, width of the groove is equal, linearly increasing, linearly decreasing, periodically varying, increasing first and decreasing after, stepped increasing and stepped decreasing.

19. The preparation method of the semiconductor structure according to claim 12, wherein, the third nitride semiconductor layer comprises a first sub-layer of the third nitride semiconductor layer and a second sub-layer of the third nitride semiconductor layer,
the first sub-layer and the second sub-layer are located from a bottom of the third nitride semiconductor layer to a top of the third nitride semiconductor layer, and
a doping concentration of the first sub-layer of the third nitride semiconductor layer is lower than a doping concentration of the second sub-layer of the third nitride semiconductor layer.

20. The preparation method of the semiconductor structure according to claim 12, wherein, from bottom-up direction, the source region comprises a first sub-layer and a second sub-layer, doping concentration of the first sub-layer of the source region is lower than doping concentration of the second sub-layer of the source region, and the top of the upper surface of the first sub-layer of the source region does not exceed the groove.
